(19) United States
(12) Patent Application Publication
(10) Pub. No.: US 2026/0255711 A1
(43) Pub. Date: Aug. 27, 2026

(54) PHOTODETECTION DEVICE AND ELECTRONIC DEVICE

(71) Applicant: SONY SEMICONDUCTOR SOLUTIONS CORPORATION, KANAGAWA (JP)

(72) Inventors: YUKA OHKUBO, KANAGAWA (JP); YUTARO KOMURO, KANAGAWA (JP); KEISUKE TERADA, KANAGAWA (JP)

(21) Appl. No.: 18/578,327

(22) PCT Filed: Jul. 20, 2022
(86) PCT No.: PCT/JP2022/028213

§ 371 Date: Jan. 11, 2024

(30) Foreign Application Priority Data
Aug. 3, 2021 (JP) 2021-127112

(51) Int. Cl. H10F 39/00

(52) U.S. Cl. CPC H10F 39/8063

(57) ABSTRACT

The present disclosure relates to a photodetection device and an electronic device that are capable of condensing light more efficiently. Provided is a photodetection device that includes a plurality of pixels each having a photoelectric conversion region, and an on-chip microlens formed corresponding to each pixel. The on-chip microlens has a second refractive index that is a refractive index higher than a first refractive index. A gap having a tapered cross-sectional shape is formed as a region separating on-chip microlenses. The present disclosure can be applied to, for example, an image sensor that supports near-infrared rays.

### TECHNICAL FIELD

The present disclosure relates to a photodetection device and an electronic device, and more particularly to a photodetection device and an electronic device capable of more efficiently condensing light.

### BACKGROUND ART

Examples of an image sensor include an image sensor that supports visible light and an image sensor that supports near-infrared rays (NIR). Patent Document 1 discloses a structure for suppressing color mixing with adjacent pixels as a structure that supports visible light.

### CITATION LIST

### Patent Document

Patent Document 1: U.S. Patent Application Publication No. 2019/0157329

### SUMMARY OF THE INVENTION

### Problems to be Solved by the Invention

While a light condensing structure using an on-chip microlens is known and optimized for visible light, a technique for efficiently condensing near-infrared rays has been required.

The present disclosure has been made in view of such a situation, and an object of the present disclosure is to enable more efficient light condensing.

### Solutions to Problems

A photodetection device according to one aspect of the present disclosure includes: a plurality of pixels each having a photoelectric conversion region; and an on-chip microlens formed corresponding to each pixel, in which the on-chip microlens has a second refractive index that is a refractive index higher than a first refractive index, and a gap having a tapered cross-sectional shape is formed as a region separating on-chip microlenses.

An electronic device according to one aspect of the present disclosure is an electronic device on which a photodetection device is mounted, the photodetection device includes: a plurality of pixels each having a photoelectric conversion region; and an on-chip microlens formed corresponding to each pixel, in which the on-chip microlens has a second refractive index that is a refractive index higher than a first refractive index, and a gap having a tapered cross-sectional shape is formed as a region separating on-chip microlenses.

A photodetection device and an electronic device according to one aspect of the present disclosure each include: a plurality of pixels each having a photoelectric conversion region; and an on-chip microlens formed corresponding to each pixel, in which the on-chip microlens has a second refractive index that is a refractive index higher than a first refractive index, and a gap having a tapered cross-sectional shape is formed as a region separating on-chip microlenses.

Note that photodetection device according to one aspect of the present disclosure may be an independent device or an internal block constituting one device.

### BRIEF DESCRIPTION OF DRAWINGS

FIG. 1 is a view illustrating a configuration example of a solid-state imaging device.

FIG. 2 is a cross-sectional view illustrating a first example of a structure to which the present disclosure is applied.

FIG. 3 is a plan view corresponding to the cross-sectional view of FIG. 2.

FIG. 4 is a view illustrating a relationship between an incident angle and a refractive index.

FIG. 5 is a cross-sectional view illustrating a structure corresponding to pupil correction.

FIG. 6 is a plan view illustrating a structure corresponding to an end surface view of FIG. 5.

FIG. 7 is a cross-sectional view illustrating a second example of the structure to which the present disclosure is applied.

FIG. 8 is a plan view corresponding to the cross-sectional view of FIG. 7.

FIG. 9 is a cross-sectional view illustrating a third example of a structure to which the present disclosure is applied.

FIG. 10 is a plan view corresponding to the cross-sectional view of FIG. 9.

FIG. 11 is a cross-sectional view illustrating a fourth example of the structure to which the present disclosure is applied.

FIG. 12 is a plan view corresponding to the cross-sectional view of FIG. 11.

FIG. 13 is a cross-sectional view illustrating a fifth example of the structure to which the present disclosure is applied.

FIG. 14 is a plan view corresponding to the cross-sectional view of FIG. 13.

FIG. 15 is a cross-sectional view illustrating a structure corresponding to pupil correction.

FIG. 16 is a cross-sectional view illustrating a sixth example of the structure to which the present disclosure is applied.

FIG. 17 is a plan view corresponding to the cross-sectional view of FIG. 16.

FIG. 18 is a cross-sectional view illustrating a seventh example of the structure to which the present disclosure is applied.

FIG. 19 is a plan view corresponding to the cross-sectional view of FIG. 18.

FIG. 20 is a cross-sectional view illustrating a structure corresponding to pupil correction.

FIG. 21 is a cross-sectional view illustrating an eighth example of the structure to which the present disclosure is applied.

FIG. 22 is a plan view corresponding to the cross-sectional view of FIG. 21.

FIG. 23 is a cross-sectional view illustrating a ninth example of the structure to which the present disclosure is applied.

FIG. 24 is a plan view corresponding to the cross-sectional view of FIG. 23.

FIG. 25 is a cross-sectional view illustrating a tenth example of the structure to which the present disclosure is applied.

FIG. 26 is a plan view corresponding to the cross-sectional view of FIG. 25.

FIG. 27 is a cross-sectional view illustrating an eleventh example of the structure to which the present disclosure is applied.

FIG. 28 is a plan view corresponding to the cross-sectional view of FIG. 27.

FIG. 29 is a cross-sectional view illustrating a structure corresponding to pupil correction.

FIG. 30 is a view illustrating a first example of a manufacturing method.

FIG. 31 is a view illustrating the first example of the manufacturing method.

FIG. 32 is a view illustrating a second example of the manufacturing method.

FIG. 33 is a block diagram illustrating a configuration example of an electronic device on which the photodetection device to which the present disclosure is applied is mounted.

### MODE FOR CARRYING OUT THE INVENTION

### 1. Embodiments of Present Disclosure

### (Configuration of Solid-State Imaging Device)

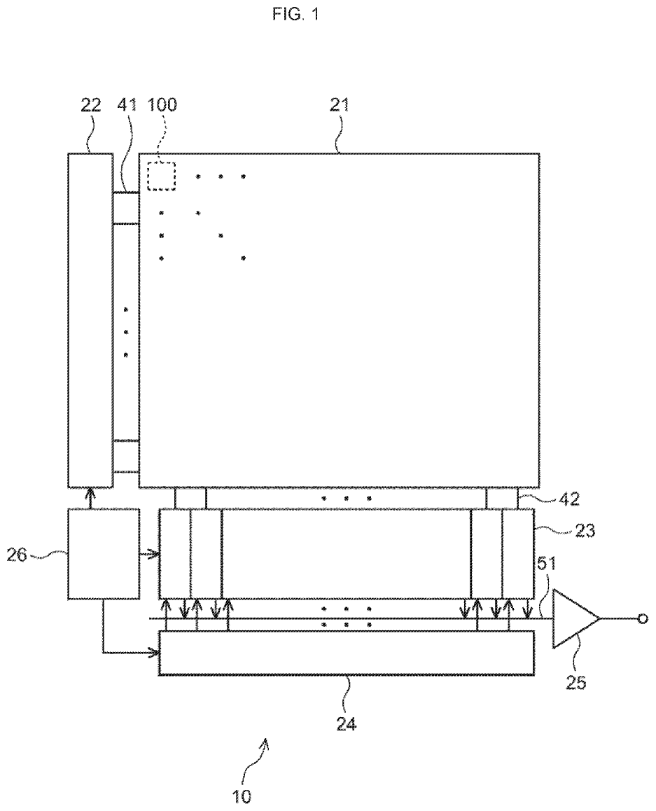

FIG. 1 is a view illustrating a configuration example of a solid-state imaging device.

In FIG. 1, a solid-state imaging device 10 is an image sensor that supports near-infrared rays (NIR). The solid-state imaging device 10 is an example of a photodetection device to which the present disclosure is applied. The solid-state imaging device 10 is constituted by a pixel array unit 21, a vertical drive unit 22, a signal processing unit 23, a horizontal drive unit 24, an output unit 25, and a control unit 26.

The pixel array unit 21 has a plurality of pixels 100 two-dimensionally arrayed on a substrate containing silicon (Si). The pixel 100 has a photoelectric conversion region containing a photodiode.

In the pixel array unit 21, for the plurality of pixels 100 two-dimensionally arrayed, a pixel drive line 41 is formed on a row-by-row basis and connected to the vertical drive unit 22, and a vertical signal line 42 is formed on a column-by-column basis and connected to the signal processing unit 23.

The vertical drive unit 22 is constituted by a shift register, an address decoder, and the like, and drives each pixel 100 arrayed in the pixel array unit 21. A pixel signal output from each pixel 100 selectively scanned by the vertical drive unit 22 is supplied to the signal processing unit 23 through the vertical signal line 42.

The signal processing unit 23 performs predetermined signal processing on the pixel signal output from each pixel 100 in a selected row through the vertical signal line 42 on a pixel column-by-pixel column basis in the pixel array unit 21. As the signal processing, for example, processing such as readout processing and noise removal processing is performed.

The horizontal drive unit 24 is constituted by a shift register, an address decoder, and the like, and sequentially selects a unit circuit corresponding to a pixel column of the signal processing unit 23. As a result of selective scanning by the horizontal drive unit 24, the pixel signal subjected to the signal processing by the signal processing unit 23 is output to the output unit 25 through a horizontal signal line 51.

The output unit 25 performs predetermined signal processing on pixel signals input in sequence from respective parts of the signal processing unit 23 through the horizontal signal line 51, and outputs signals obtained as a result of the signal processing.

The control unit 26 is constituted by a timing generator that generates various types of timing signals and the like, and controls driving of the vertical drive unit 22, the signal processing unit 23, the horizontal drive unit 24, and the like on the basis of the various types of timing signals generated by the timing generator.

### (Configuration of Pixels)

Next, a structure including the pixels 100 two-dimensionally arrayed in the pixel array unit 21 in the solid-state imaging device 10 will be described.

### First Example

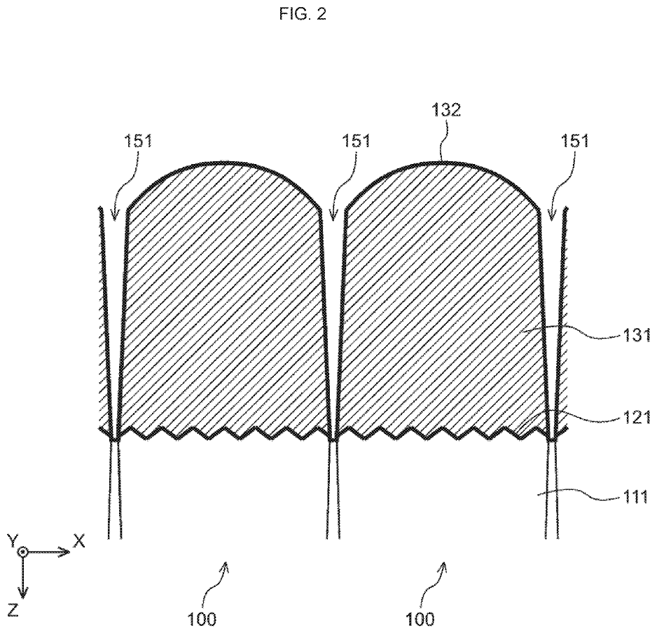

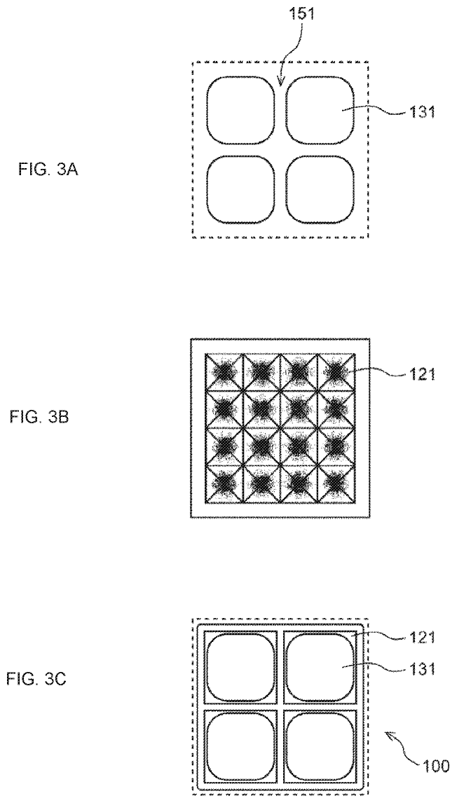

FIGS. 2 and 3 are views each illustrating a first example of a structure to which the present disclosure is applied.

FIG. 2 illustrates a cross-sectional structure of a structure including the pixels 100. FIG. 3 is a plan view when each layer is viewed on an XY plane in a case where a depth direction is a Z direction in the cross-sectional structure of FIG. 2. These relationships similarly apply to the other drawings which will be described later.

In FIG. 2, the pixel 100 has a photoelectric conversion region formed on a silicon substrate 111. For example, the photoelectric conversion region includes a semiconductor region of a second conductivity type in a well region of a first conductivity type formed in the silicon substrate 111. The first conductivity type can be a p-type, and the second conductivity type can be an n-type.

An antireflection layer 121 is formed on the surface of the silicon substrate 111. The antireflection layer 121 is formed in a moth-eye structure that forms a fine uneven shape. The antireflection layer 121 has the moth-eye structure, whereby reflection of incident light on the silicon substrate 111 can be suppressed. Therefore, in each pixel 100, it is possible to retain incident light in the photoelectric conversion region.

B of FIG. 3 illustrates a plan view of the antireflection layer 121. In B of FIG. 3, a part where two lines intersect in a rectangle represents a recess portion of the moth-eye structure. Although simplified in B of FIG. 3, in the antireflection layer 121, a large number of such uneven shapes are arranged at predetermined intervals.

On the antireflection layer 121, an on-chip microlens 131 corresponding to each pixel 100 is formed. A surface film 132 is formed on the surface of the on-chip microlens 131.

The on-chip microlens 131 is a high refractive index lens containing a material having a high refractive index. For example, in a case where a refractive index of an on-chip microlens used in the image sensor that supports visible light is 1.6, the refractive index of the on-chip microlens 131 can be a refractive index that is higher than 1.6. More specifically, the refractive index of the on-chip microlens 131 can be set at 1.9.

As a material of the on-chip microlens 131, for example, amorphous silicon (a-Si), silicon nitride (SiN), a high refractive index resin, tantalum (Ta), titanium (Ti), aluminum oxide (AlO), a high refractive index metal oxide film, or the like can be used.

A gap 151 having a tapered cross-sectional shape is formed as a region separating the on-chip microlenses 131. The gap 151 has a tapered shape that narrows toward the surface of the silicon substrate 111 and penetrates to the surface of the silicon substrate 111. The gap 151 is also referred to as an air-gap.

A of FIG. 3 illustrates a plan view of the on-chip microlens 131. A of FIG. 3 illustrates four on-chip microlenses 131 corresponding to four adjacent pixels 100 (2×2 pixels). In addition, a plan view in C of FIG. 3 is a view when the plan view in A of FIG. 3 and the plan view in B of FIG. 3 are overlapped and viewed from a light incident side.

As illustrated in A of FIG. 3, the gap 151 is formed between the on-chip microlenses 131. The gap 151 is formed in a lattice shape (square lattice shape) in a plan view, and the entire periphery of each on-chip microlens 131 is surrounded by the gap 151.

The gap 151 has a shape in which a width decreases in a depth direction (Z direction), that is, a shape in which a width of an upper portion (top) increases and a width of a lower portion (bottom) decreases. For example, when the width of the lower portion is 100 nm, the width of the upper portion can be larger than 100 nm. An angle of a side wall of the gap 151 can be calculated, for example, using the following Expression (1).

$$\begin{matrix}[ Expression 1 ] & \\ {θ}_{0} = Arc sin ( \frac{{n}_{1}}{{n}_{0}} ) & ( 1 )\end{matrix}$$

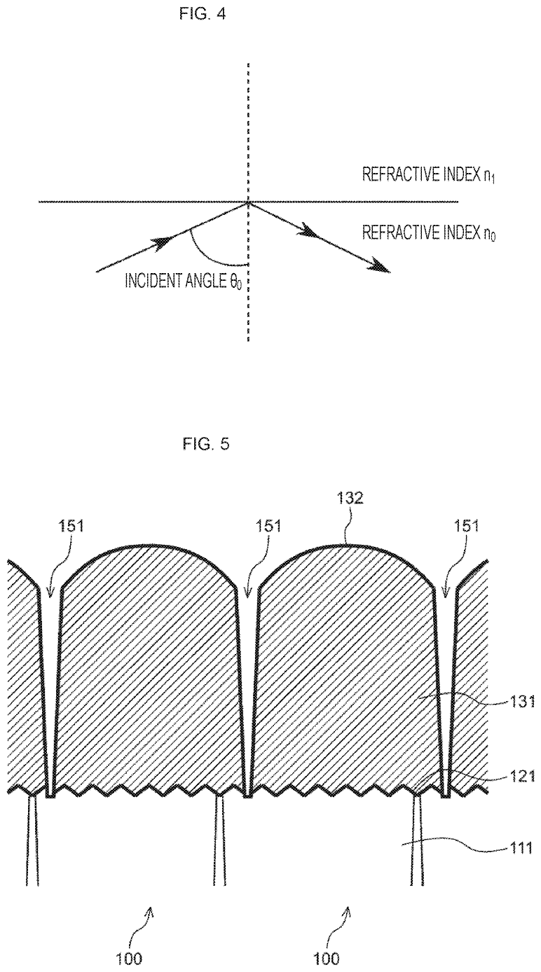

In Expression (1), θ₀ represents an incident angle, and no and n₁ represent refractive indexes. A relationship among the incident angle θ₀, the refractive index n₀, and the refractive index n₁ is as illustrated in FIG. 4. The refractive index n₁ represents the refractive index of air filled in the gap 151, and n₁=1. The refractive index n₀ represents the refractive index of the material of the on-chip microlens 131. Note that in a case where the refraction angle reaches 90°, light cannot be refracted.

For example, in a case where the material of the on-chip microlens 131 is silicon nitride (SiN), the refractive index n₀ represents a refractive index of silicon nitride (SiN). The refractive index of silicon nitride (SiN) has wavelength dependency.

In a case where the refractive index n₀ of the on-chip microlens 131 is n₀=1.9, θ₀=32° is calculated as the incident angle θ₀ by using Expression (1). In this case, as the side wall of the gap 151, a side wall having an angle at which light is totally reflected at an incident angle of 32° is formed.

Note that the above description has been given of the tapered cross-sectional shape as the shape of the gap 151, but an inverted triangular shape in which a lower portion has an acute angle may be adopted as the shape in which the width decreases in the depth direction (Z direction).

As described above, in the first example of the structure to which the present disclosure is applied, the high refractive index lens is used as the on-chip microlens 131, and the gap 151 having the tapered cross-sectional shape is formed as the region separating the on-chip microlenses 131.

With such a structure, a difference in refractive index between the on-chip microlens 131 and the gap 151 increases and a total reflection angle becomes deeper. Furthermore, with the tapered structure, an incident angle of light obliquely incident on the gap 151 can be made shallower. Therefore, it is possible to efficiently reflect incident light and retain the incident light in the photoelectric conversion region of each pixel 100. With such an effect of confining the incident light, an optical distance for silicon absorption is extended, whereby sensitivity can be improved. In addition, with formation of the antireflection layer 121 having the moth-eye structure, the effect of confining the incident light can be further enhanced.

By the way, in the image sensor that supports near-infrared rays, a beam waist cannot be narrowed in an existing lens, and there is a possibility that vignetting occurs in a light-shielding film or color mixing occurs in adjacent pixels. Furthermore, in the image sensor that supports visible light, a structure has been proposed in which vignetting or color mixing due to the light-shielding film is suppressed in a visible light region by forming a separation wall of a gap between color filters.

However, in the above-mentioned, proposed structure, a difference in refractive index between the gap and the lens is small, and a sufficient effect has not been obtained. In addition, since the color filters are used in the image sensor that supports visible light, a desired gap (air gap) can be formed using the gap between the color filters. On the other hand, since a color filter is not used in the image sensor that supports near-infrared rays, a new structure has been required to be proposed.

Therefore, in the present disclosure, in the solid-state imaging device 10 that is the image sensor that supports near-infrared rays, a high refractive index lens is used as the on-chip microlens 131, and the gap 151 having the tapered cross-sectional shape is formed between the on-chip microlenses 131 in order to narrow a beam of near-infrared light and prevent color mixing with adjacent pixels. Therefore, in the solid-state imaging device 10, near-infrared rays can be condensed efficiently.

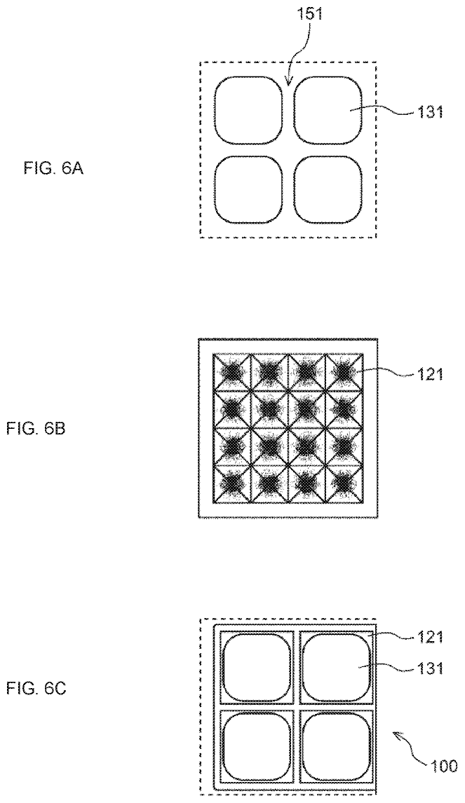

FIGS. 5 and 6 each illustrate a structure in a case where the structure illustrated in FIGS. 2 and 3 is made to correspond to pupil correction.

In the solid-state imaging device 10, pupil correction is performed to align the center of an optical axis of the on-chip microlens 131 with an optical axis of the photoelectric conversion region in a central portion of a pixel region, and shift a center position of the on-chip microlens 131 in accordance with a direction of a principal ray toward a peripheral portion of the pixel region. The pixel region mentioned herein is a region in which the plurality of pixels 100 is two-dimensionally arrayed in the pixel array unit 21.

As illustrated in the cross-sectional structure of FIG. 5, the on-chip microlens 131 is formed such that the center of the lens is shifted from the center of the photoelectric conversion region to the center side of the pixel region, from the central portion of the pixel region toward the peripheral portion of the pixel region. In the cross-sectional structure of FIG. 5, each on-chip microlens 131 and the gap 151 formed between the on-chip microlenses 131 are shifted in the X direction in the drawing in accordance with pupil correction. Similarly, in a plan view in C of FIG. 6, the on-chip microlens 131 and the gap 151 are shifted in accordance with pupil correction.

### Second Example

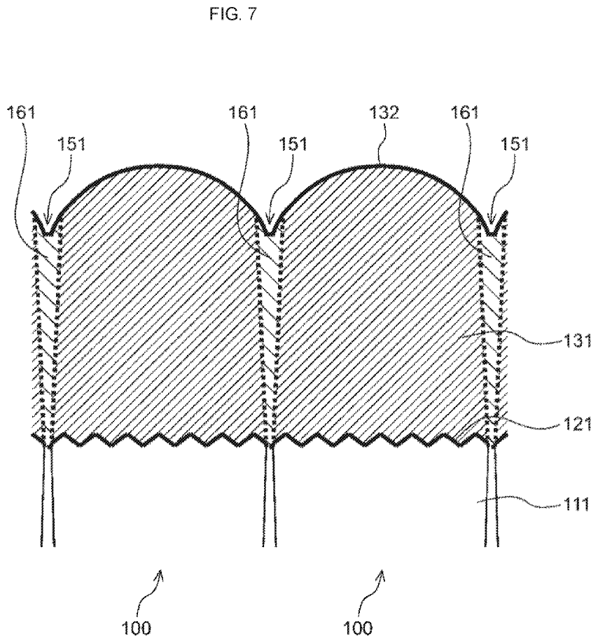

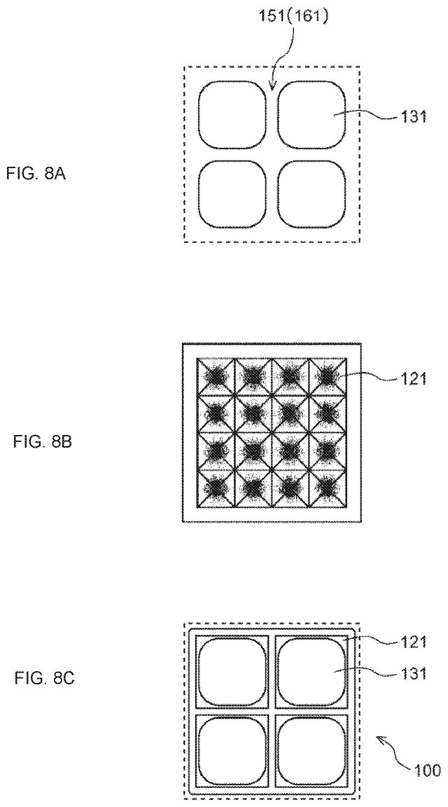

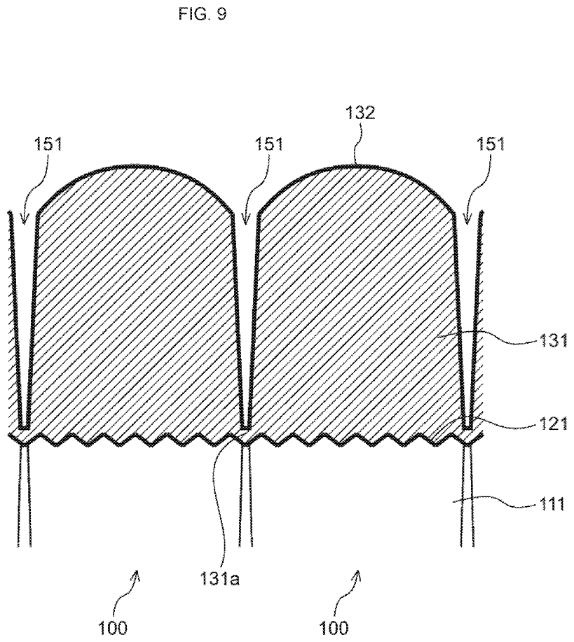

FIGS. 7 and 8 are views each illustrating a second example of a structure to which the present disclosure is applied. In FIGS. 7 and 8, parts corresponding to those in FIGS. 2 and 3 are denoted by the same reference numerals, and description of the parts will be omitted as appropriate. Note that description of parts denoted by the same reference numerals will be omitted as appropriate also in the following drawings.

The cross-sectional structure of FIG. 7 has a structure in which an embedded film 161 is embedded in the gap 151 having the tapered cross-sectional shape as compared with the cross-sectional structure of FIG. 2. That is, the gap 151 is filled with air in the cross-sectional structure of FIG. 2, but the gap 151 is filled with the embedded film 161 in the cross-sectional structure of FIG. 7.

As a material of the embedded film 161, for example, silicon oxide (SiO₂) or the like can be used. A recess on an upper portion of the embedded film 161 is continuous to the surface of the on-chip microlens 131, and the surface film 132 is formed.

As described above, in the second example of the structure to which the present disclosure is applied, the high refractive index lens is used as the on-chip microlens 131, the gap 151 having the tapered cross-sectional shape is formed as the region separating the on-chip microlenses 131, and the embedded film 161 is embedded in the gap 151.

With such a structure, a difference in refractive index between the on-chip microlens 131 and the gap 151 (the embedded film 161 filled in the gap 151) increases and a total reflection angle becomes deeper. Furthermore, with the tapered structure, an incident angle of light obliquely incident on the gap 151 can be made shallower. Therefore, it is possible to efficiently reflect incident light and retain the incident light in the photoelectric conversion region of each pixel 100. Therefore, near-infrared rays can be efficiently condensed.

### Third Example

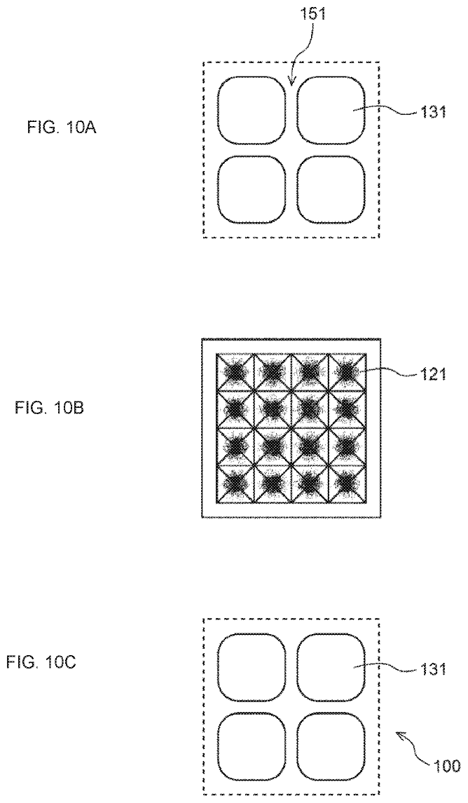

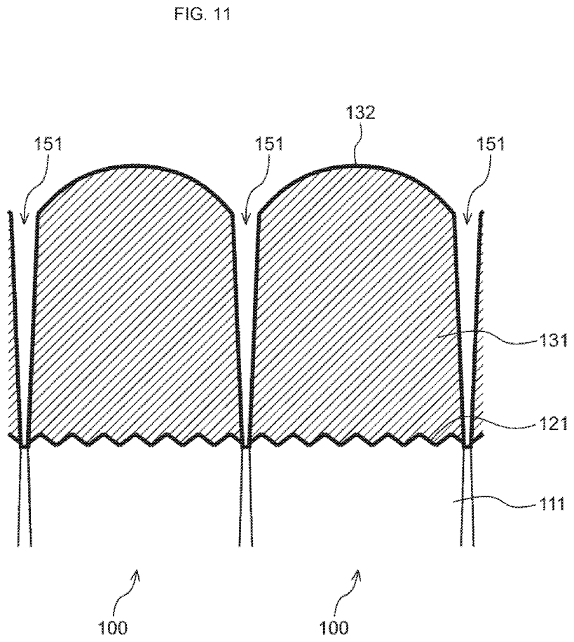

FIGS. 9 and 10 are views each illustrating a third example of the structure to which the present disclosure is applied.

In a cross-sectional structure of FIG. 9, as compared with the cross-sectional structure of FIG. 2, the gap 151 having the tapered cross-sectional shape does not reach the surface of the silicon substrate 111 and does not penetrate to the surface of the silicon substrate 111. That is, in the cross-sectional structure of FIG. 9, the gap 151 has a structure in which a lower portion (bottom surface) thereof is formed between the on-chip microlenses 131 (a structure in which the gap 151 is stopped in the middle of the on-chip microlens 131), and a layer 131a remains between the adjacent on-chip microlenses 131.

As described above, in the third example of the structure to which the present disclosure is applied, the high refractive index lens is used as the on-chip microlens 131, the gap 151 having the tapered cross-sectional shape is formed as the region separating the on-chip microlenses 131, and the gap 151 does not reach the surface of the silicon substrate 111.

With such a structure, similarly to the first example of the structure, it is possible to efficiently reflect incident light and retain the incident light in the photoelectric conversion region of each pixel 100. Therefore, near-infrared rays can be efficiently condensed.

### Fourth Example

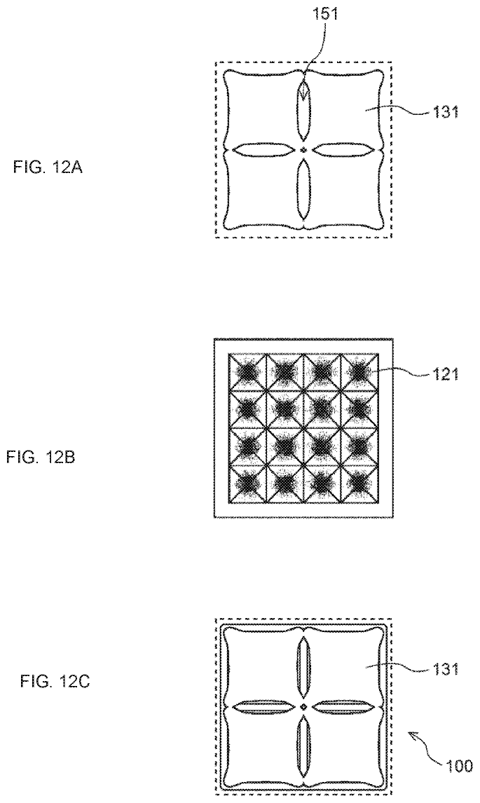

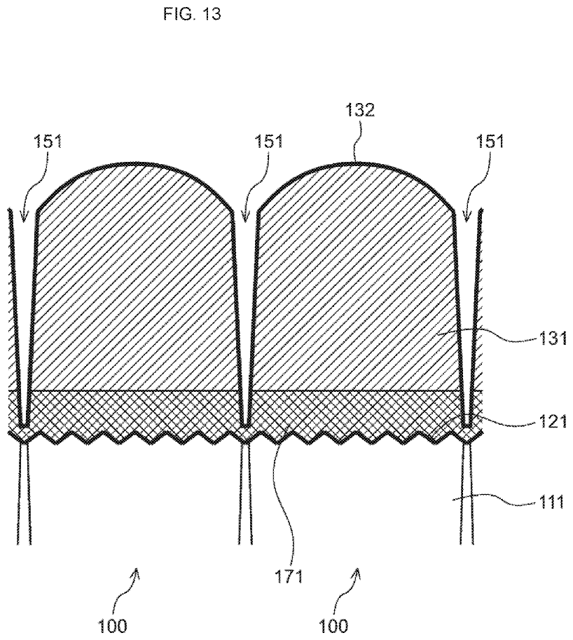

FIGS. 11 and 12 are views each illustrating a fourth example of the structure to which the present disclosure is applied.

In the cross-sectional structure of FIG. 11, the shape of the on-chip microlens 131 is different from that in the cross-sectional structure of FIG. 2. That is, in a plan view in A of FIG. 12, the gaps 151 are not formed in a lattice shape as compared with the plan view in A of FIG. 3, but each of the four on-chip microlenses 131 has a part that does not become the gap 151 (on chip lens (OCL) gapless) in a diagonal direction, so that a structure having the gaps 151 in four directions of upper, lower, left, and right directions is obtained. Note that the shape of the gap 151 is not limited to the shape illustrated in the plan view of A of FIG. 12, and may be another shape.

As described above, in the fourth example of the structure to which the present disclosure is applied, the high refractive index lens is used as the on-chip microlens 131, the gap 151 having the tapered cross-sectional shape is formed as the region separating the on-chip microlenses 131, and the on-chip microlens 131 has the gaps 151 in four directions of upper, lower, left, and right directions in a plan view.

With such a structure, similarly to the first example of the structure, it is possible to efficiently reflect incident light and retain the incident light in the photoelectric conversion region of each pixel 100. Therefore, near-infrared rays can be efficiently condensed.

### Fifth Example

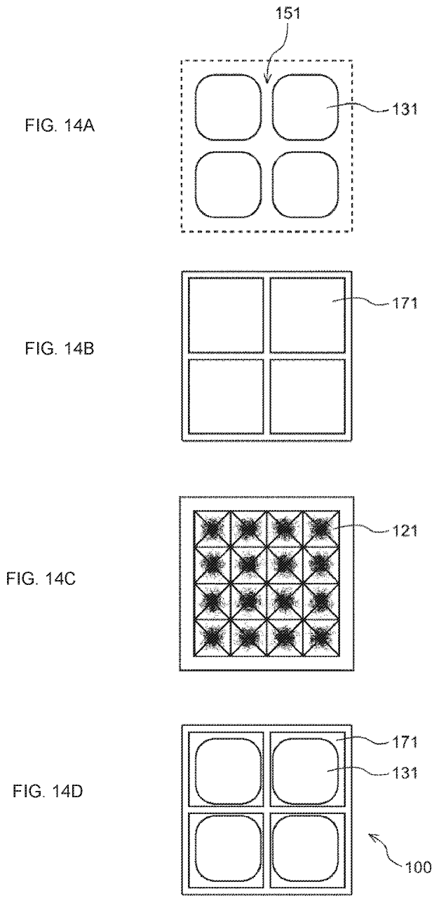

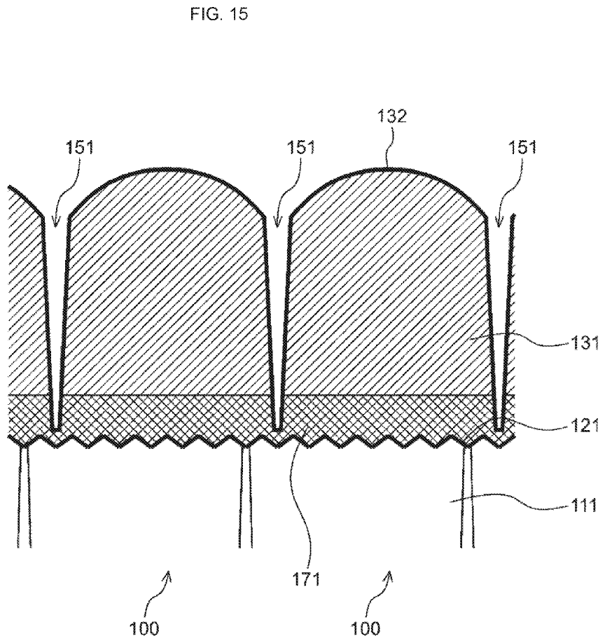

FIGS. 13 and 14 are views each illustrating a fifth example of the structure to which the present disclosure is applied.

In a cross-sectional structure of FIG. 13, as compared with the cross-sectional structure of FIG. 2, an intermediate layer 171 is formed on the antireflection layer 121, and the on-chip microlens 131 is formed on the intermediate layer 171. In other words, the intermediate layer 171 is formed between the antireflection layer 121 and the on-chip microlens 131.

The intermediate layer 171 can contain a material having a high refractive index. For example, a refractive index of the intermediate layer 171 can be higher than 1.6, similarly to the refractive index of the on-chip microlens 131.

As a material of the intermediate layer 171, for example, silicon oxide (SiO), AO, or the like can be used. Note that in a case where silicon oxide (SiO) or the like is used as the material, the intermediate layer 171 can be formed by film formation performed in a step using high density plasma (HDP). B of FIG. 14 illustrates a plan view of the intermediate layer 171.

The gap 151 has a tapered shape that narrows toward the surface of the silicon substrate 111, but has a structure of not reaching the surface of the silicon substrate 111 and not penetrating the intermediate layer 171. That is, in the cross-sectional structure of FIG. 13, the gap 151 has a structure in which a lower portion (bottom surface) thereof is formed on the intermediate layer 171 (a structure in which the gap 151 is stopped in the middle of the intermediate layer 171).

As described above, in the fifth example of the structure to which the present disclosure is applied, the high refractive index lens is used as the on-chip microlens 131, the gap 151 having the tapered cross-sectional shape is formed as the region separating the on-chip microlenses 131, and the intermediate layer 171 is formed between the silicon substrate 111 and the on-chip microlens 131.

With such a structure, similarly to the first example of the structure, it is possible to efficiently reflect incident light and retain the incident light in the photoelectric conversion region of each pixel 100. Therefore, near-infrared rays can be efficiently condensed.

FIG. 15 illustrates a structure in a case where the structure illustrated in FIG. 13 is made to correspond to pupil correction.

As described above, in a case where pupil correction is performed, the on-chip microlens 131 is formed such that the center of the lens is shifted from the center of the photoelectric conversion region to the center side of the pixel region, from the central portion of the pixel region toward the peripheral portion of the pixel region. In the cross-sectional structure of FIG. 15, the on-chip microlens 131, the intermediate layer 171, and the gap 151 formed therein are shifted in the X direction in the drawing in accordance with pupil correction.

### Sixth Example

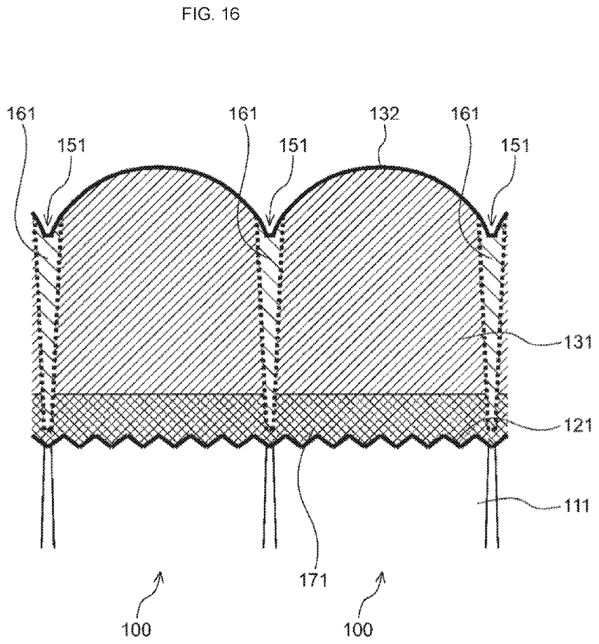

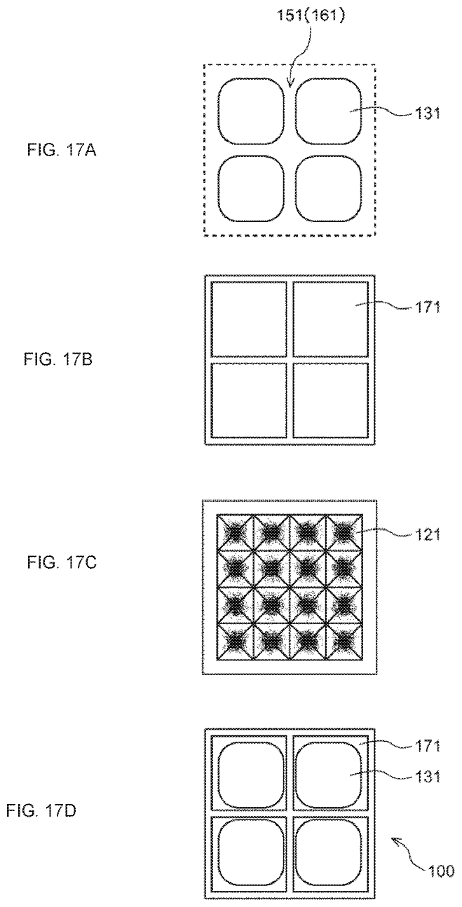

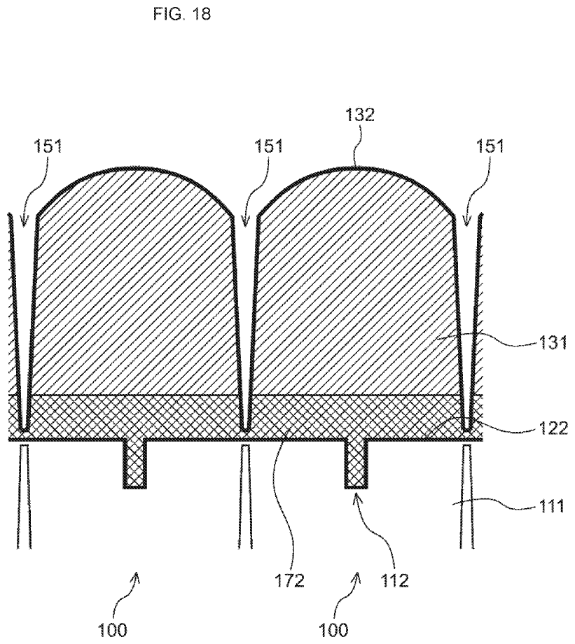

FIGS. 16 and 17 are views each illustrating a sixth example of the structure to which the present disclosure is applied.

The cross-sectional structure of FIG. 16 is a structure in which the embedded film 161 is embedded in the gap 151 as compared with the cross-sectional structure of FIG. 13. That is, the gap 151 is filled with air in the cross-sectional structure of FIG. 13, but is filled with the embedded film 161 such as silicon oxide (SiO₂) in the cross-sectional structure of FIG. 16.

As described above, in the sixth example of the structure to which the present disclosure is applied, the high refractive index lens is used as the on-chip microlens 131, the gap 151 having the tapered cross-sectional shape is formed as the region separating the on-chip microlenses 131, the intermediate layer 171 is formed, and furthermore, the embedded film 161 is embedded in the gap 151.

With such a structure, similarly to the first example of the structure, it is possible to efficiently reflect incident light and retain the incident light in the photoelectric conversion region of each pixel 100. Therefore, near-infrared rays can be efficiently condensed.

### Seventh Example

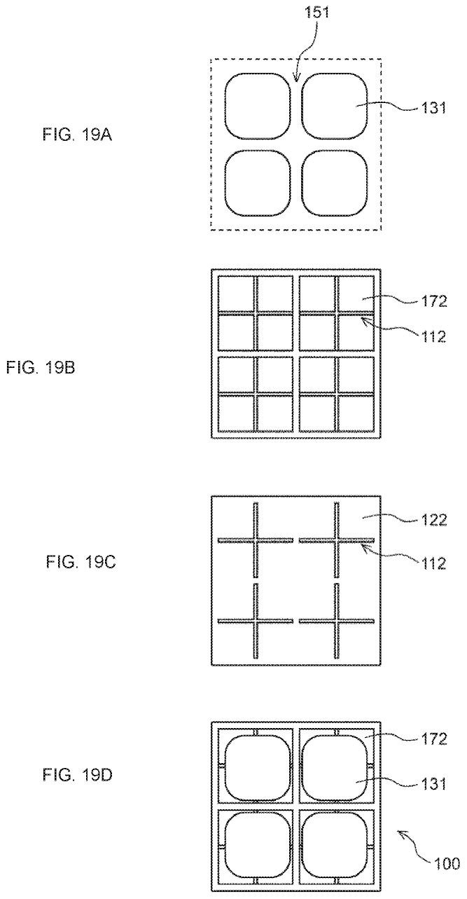

FIGS. 18 and 19 are views each illustrating a seventh example of the structure to which the present disclosure is applied.

A cross-sectional structure of FIG. 18 is a structure in which an antireflection layer 122 is formed instead of the antireflection layer 121, an intermediate layer 172 is formed as an upper layer above the antireflection layer 122, and the on-chip microlens 131 is formed as an upper layer above the intermediate layer 172, as compared with the cross-sectional structure of FIG. 2.

The antireflection layer 122 is formed on the surface of the silicon substrate 111 and has fine recesses 112. The recess 112 is filled with a material used for the intermediate layer 172. C of FIG. 19 illustrates a plan view of the antireflection layer 122. As illustrated in C of FIG. 19, in the antireflection layer 122, the recess 112 is formed in a cross shape.

Since the antireflection layer 122 has a structure in which the recess 112 having the cross shape is formed, it is possible to suppress reflection of incident light on the silicon substrate 111. Therefore, in each pixel 100, it is possible to retain incident light in the photoelectric conversion region. Note that as the shape of the recess 112, a shape other than the cross shape may be formed as a predetermined shape.

As the material of the intermediate layer 172, silicon oxide (SiO) or the like can be used similarly to the intermediate layer 171. B of FIG. 19 illustrates a plan view of the intermediate layer 172. As illustrated in B of FIG. 19, the intermediate layer 172 has a shape in which a part thereof is embedded in a cross shape corresponding to the shape of the recess 112 of the antireflection layer 122 to be a lower layer thereof.

The gap 151 has a tapered shape that narrows toward the surface of the silicon substrate 111, but has a structure of not reaching the surface of the silicon substrate 111 and not penetrating the intermediate layer 172. That is, in the cross-sectional structure of FIG. 18, the gap 151 has a structure in which a lower portion (bottom surface) thereof is formed on the intermediate layer 172 (a structure in which the gap 151 is stopped in the middle of the intermediate layer 172).

As described above, in the seventh example of the structure to which the present disclosure is applied, the high refractive index lens is used as the on-chip microlens 131, the gap 151 having the tapered cross-sectional shape is formed as the region separating the on-chip microlenses 131, and the antireflection layer 122 and the intermediate layer 172 are formed.

With such a structure, similarly to the first example of the structure, it is possible to efficiently reflect incident light and retain the incident light in the photoelectric conversion region of each pixel 100. Therefore, near-infrared rays can be efficiently condensed.

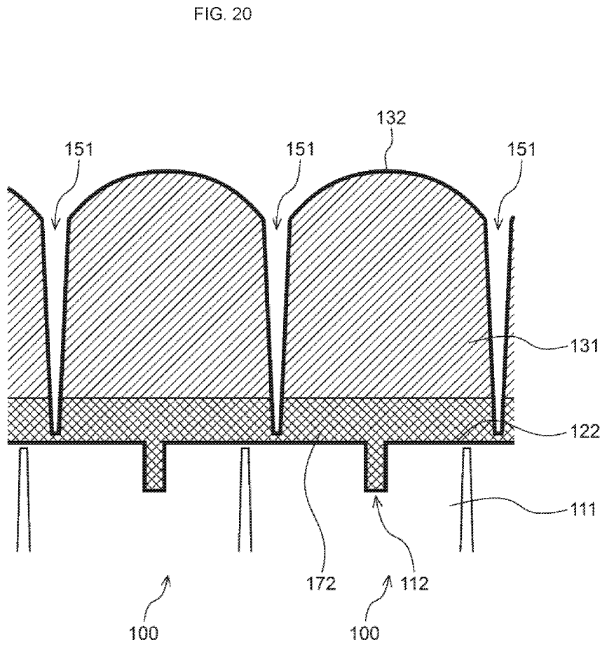

FIG. 20 illustrates a structure in a case where the structure illustrated in FIG. 18 is made to correspond to pupil correction.

As illustrated in the cross-sectional structure of FIG. 20, in a case where pupil correction is performed, the on-chip microlens 131, the intermediate layer 172, and the gap 151 formed therein are shifted in the X direction in the drawing in accordance with pupil correction.

### Eighth Example

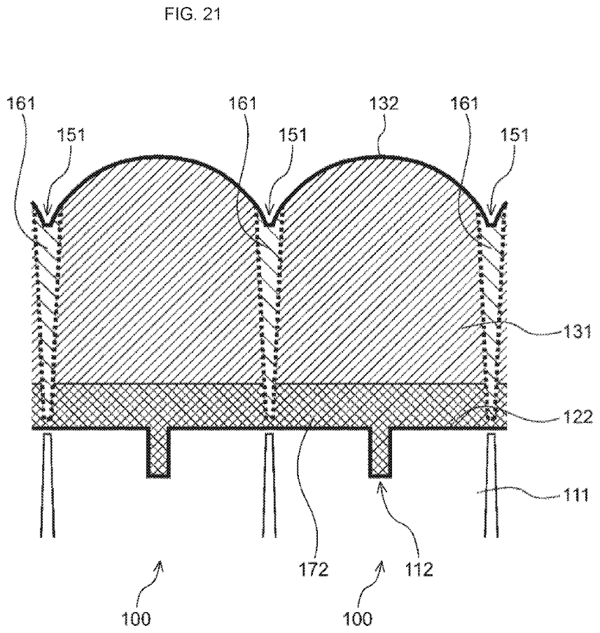

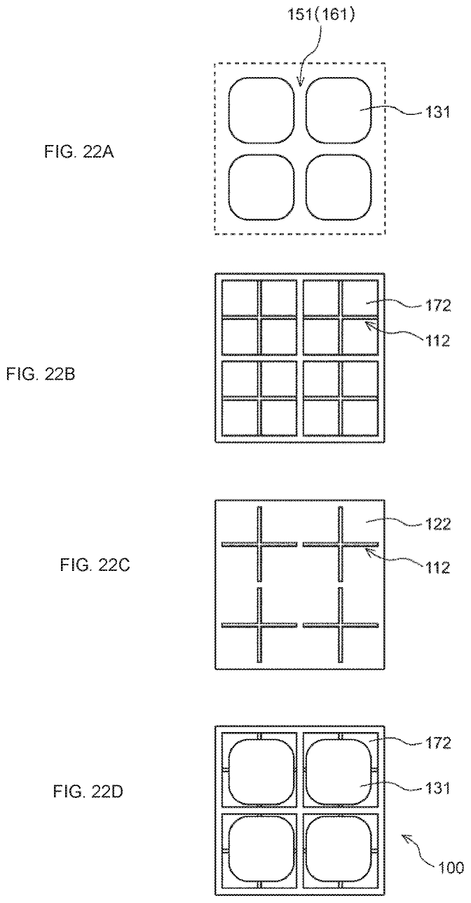

FIGS. 21 and 22 are views each illustrating an eighth example of the structure to which the present disclosure is applied.

The cross-sectional structure of FIG. 21 is a structure in which the embedded film 161 is embedded in the gap 151 as compared with the cross-sectional structure of FIG. 18. That is, the gap 151 is filled with air in the cross-sectional structure of FIG. 18, but is filled with the embedded film 161 such as silicon oxide (SiO₂) in the cross-sectional structure of FIG. 21.

As described above, in the eighth example of the structure to which the present disclosure is applied, the high refractive index lens is used as the on-chip microlens 131, the gap 151 having the tapered cross-sectional shape is formed as the region separating the on-chip microlenses 131, the antireflection layer 122 and the intermediate layer 172 are formed, and furthermore, the embedded film 161 is embedded in the gap 151.

With such a structure, similarly to the first example of the structure, it is possible to efficiently reflect incident light and retain the incident light in the photoelectric conversion region of each pixel 100. Therefore, near-infrared rays can be efficiently condensed.

### Ninth Example

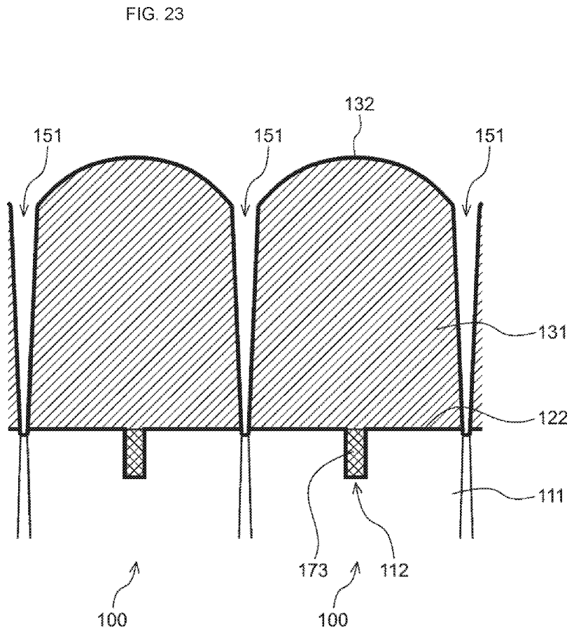

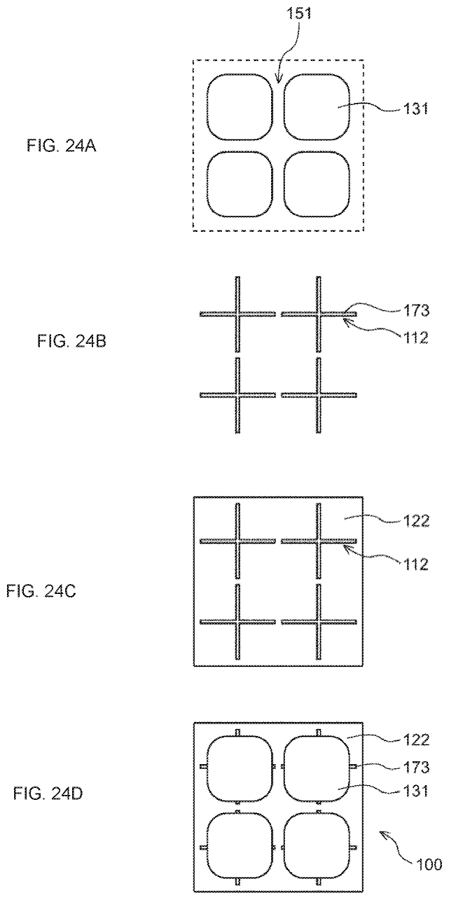

FIGS. 23 and 24 are views each illustrating a ninth example of the structure to which the present disclosure is applied.

A cross-sectional structure of FIG. 23 is a structure in which the antireflection layer 122 is formed instead of the antireflection layer 121, and the on-chip microlens 131 is formed as an upper layer above the antireflection layer 122, as compared with the cross-sectional structure of FIG. 2.

The antireflection layer 122 is formed on the surface of the silicon substrate 111 and has the fine recesses 112, but the intermediate layer 173 is embedded in the recess 112.

As the material of the intermediate layer 173, silicon oxide (SiO) or the like can be used similarly to the intermediate layers 171 and 172. B of FIG. 24 illustrates a plan view of the intermediate layer 173. As illustrated in B of FIG. 24, the intermediate layer 173 has a shape of being embedded in a cross shape corresponding to the shape of the recess 112 of the antireflection layer 122.

As described above, in the ninth example of the structure to which the present disclosure is applied, the high refractive index lens is used as the on-chip microlens 131, the gap 151 having the tapered cross-sectional shape is formed as the region separating the on-chip microlenses 131, and the antireflection layer 122 and the intermediate layer 173 are formed.

With such a structure, similarly to the first example of the structure, it is possible to efficiently reflect incident light and retain the incident light in the photoelectric conversion region of each pixel 100. Therefore, near-infrared rays can be efficiently condensed.

### Tenth Example

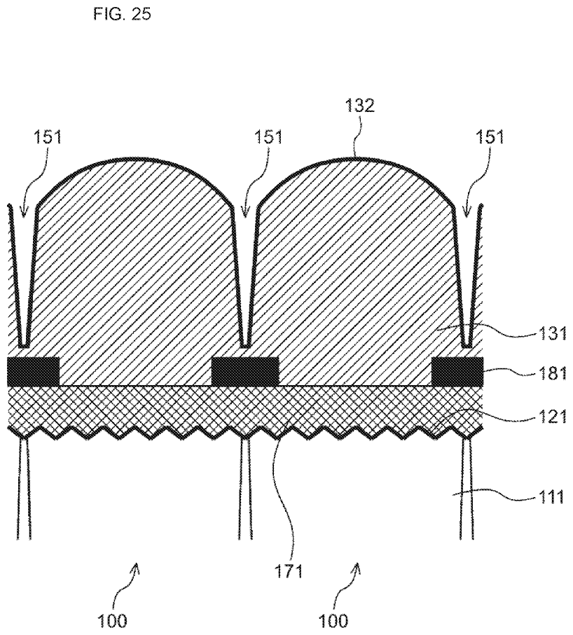

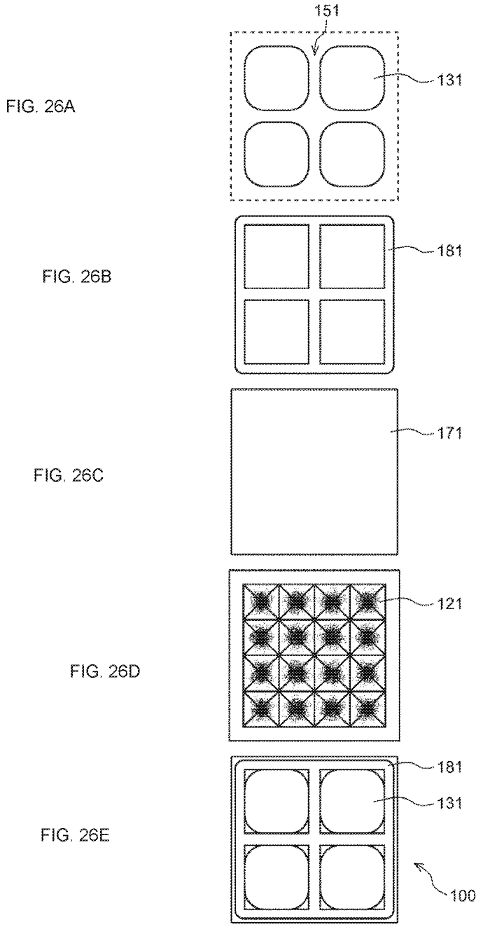

FIGS. 25 and 26 are views each illustrating a tenth example of the structure to which the present disclosure is applied.

In the cross-sectional structure of FIG. 25, as compared with the cross-sectional structure of FIG. 2, the intermediate layer 171 is formed as an upper layer above the antireflection layer 121, and the on-chip microlens 131 is formed as an upper layer above the intermediate layer 171. Furthermore, in the cross-sectional structure of FIG. 25, a light-shielding film 181 is formed on the intermediate layer 171.

The light-shielding film 181 shields adjacent pixels from incident light to suppress a stroke of the incident light between pixels. As a material of the light-shielding film 181, for example, a metal such as tungsten (W) can be used. B of FIG. 26 illustrates a plan view of the light-shielding film 181. In B of FIG. 26, the light-shielding film 181 is formed in a lattice shape with respect to the adjacent on-chip microlenses 131.

The gap 151 has a tapered shape that narrows toward the surface of the silicon substrate 111, but has a structure of not reaching the surface of the silicon substrate 111 and not penetrating the light-shielding film 181 and the intermediate layer 171. That is, in the cross-sectional structure of FIG. 25, the gap 151 has a structure in which a lower portion (bottom surface) thereof is formed between the on-chip microlenses 131 (a structure in which the gap 151 is stopped in the middle of the on-chip microlens 131).

As described above, in the tenth example of the structure to which the present disclosure is applied, the high refractive index lens is used as the on-chip microlens 131, the gap 151 having the tapered cross-sectional shape is formed as the region separating the on-chip microlenses 131, and the intermediate layer 171 and the light-shielding film 181 are formed.

With such a structure, similarly to the first example of the structure, it is possible to efficiently reflect incident light and retain the incident light in the photoelectric conversion region of each pixel 100. Therefore, near-infrared rays can be efficiently condensed.

### Eleventh Example

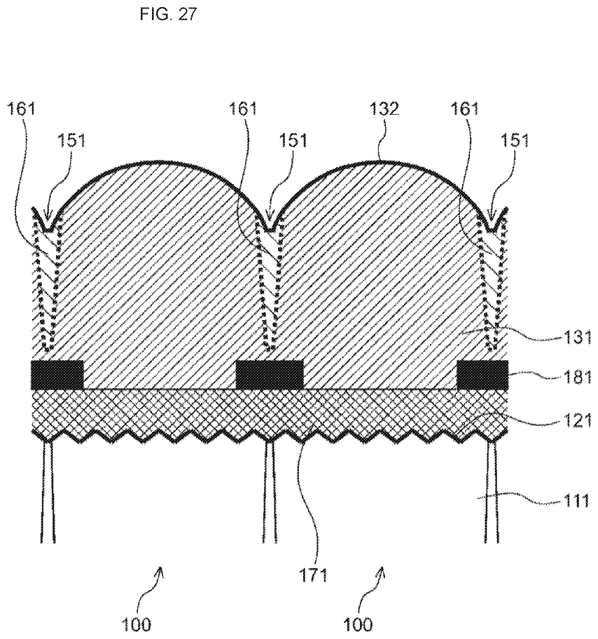

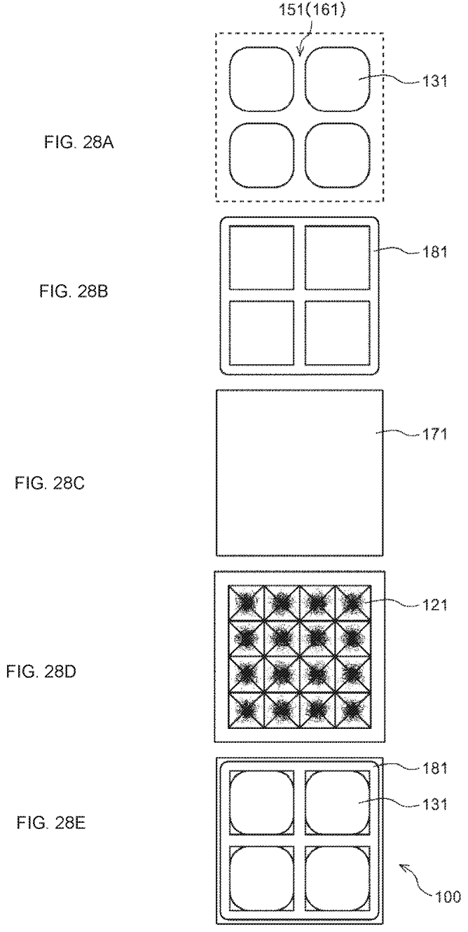

FIGS. 27 and 28 are views each illustrating an eleventh example of the structure to which the present disclosure is applied.

The cross-sectional structure of FIG. 27 is a structure in which the embedded film 161 is embedded in the gap 151 as compared with the cross-sectional structure of FIG. 25. That is, the gap 151 is filled with air in the cross-sectional structure of FIG. 25, but is filled with the embedded film 161 such as silicon oxide (SiO₂) in the cross-sectional structure of FIG. 27.

As described above, in the eleventh example of the structure to which the present disclosure is applied, the high refractive index lens is used as the on-chip microlens 131, the gap 151 having the tapered cross-sectional shape is formed as the region separating the on-chip microlenses 131, the intermediate layer 171 and the light-shielding film 181 are formed, and furthermore, the embedded film 161 is embedded in the gap 151.

With such a structure, similarly to the first example of the structure, it is possible to efficiently reflect incident light and retain the incident light in the photoelectric conversion region of each pixel 100. Therefore, near-infrared rays can be efficiently condensed.

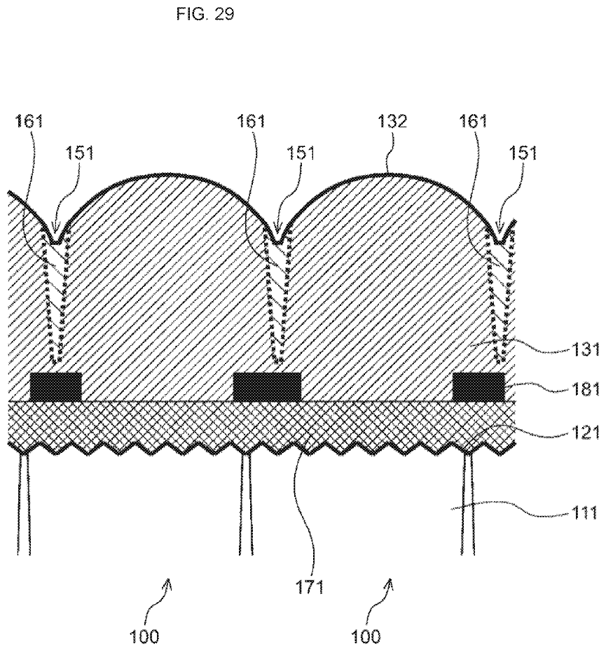

FIG. 29 illustrates a structure in a case where the structure illustrated in FIG. 27 is made to correspond to pupil correction.

As illustrated in the cross-sectional structure of FIG. 29, in a case where pupil correction is performed, the on-chip microlens 131, (the embedded film 161 filled in) the gap 151 formed therein, and the light-shielding film 181 are shifted in the X direction in the drawing in accordance with the pupil correction.

### (Manufacturing Method)

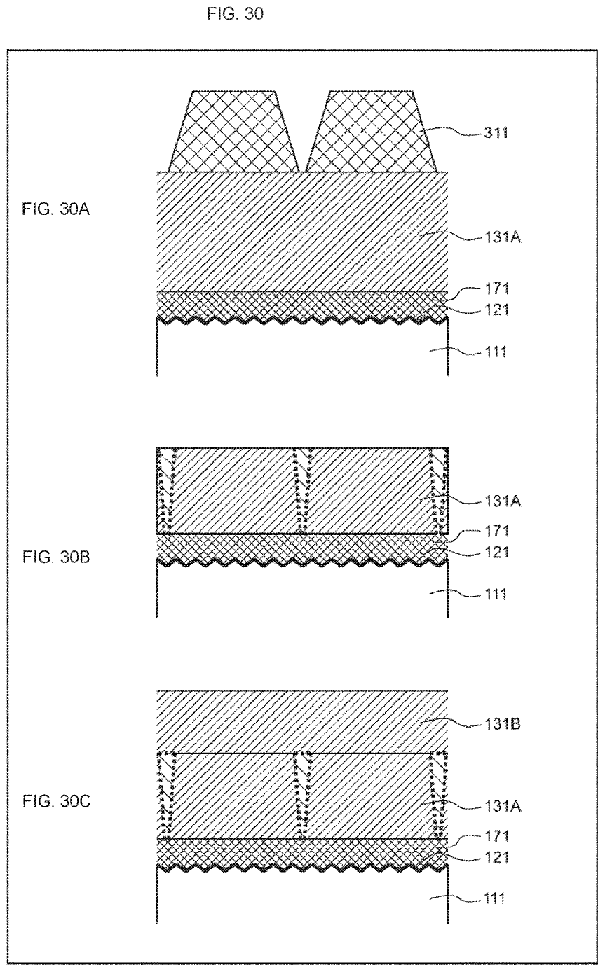

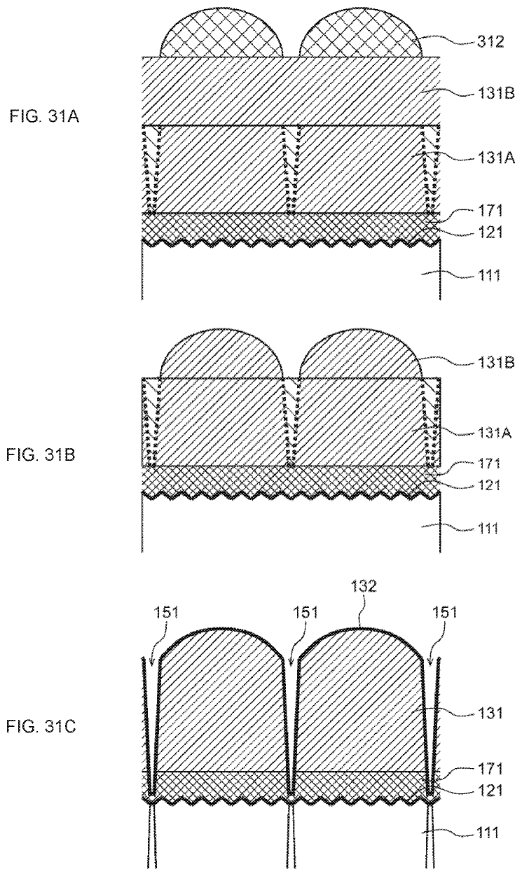

An example of a manufacturing method including steps of forming the structure to which the present disclosure is applied will be described with reference to FIGS. 30 to 32.

FIGS. 30 and 31 each illustrate an example of a manufacturing method including steps of forming the cross-sectional structure in FIG. 13. In this manufacturing method, steps after the antireflection layer 121 and the intermediate layer 171 are formed on the silicon substrate 111 are illustrated in order of steps.

In a step illustrated in A of FIG. 30, a layer 131A that contains silicon nitride (SiN) or the like, which is a material of the on-chip microlens 131, is formed on the intermediate layer 171. A tapered pattern is formed by exposure of an upper surface of the layer 131A in a pattern shape by lithography 311. In a step illustrated in B of FIG. 30, the pattern of the lithography 311 and the like are scraped off by dry etching. In a step illustrated in C of FIG. 30, silicon nitride (SiN) or the like, which is the material of the on-chip microlens 131, is applied, and a layer 131B is formed on the layer 131A.

In a step illustrated in D of FIG. 31, an upper surface of the layer 131B is exposed in a pattern by the lithography 312 to form a lens-shaped pattern. In a step illustrated in E of FIG. 31, the pattern of the lithography 312 and the like are scraped off by dry etching. In addition, a part to become the gap 151 is also removed. In a step illustrated in F of FIG. 31, the surface film 132 is formed. Through such steps, the cross-sectional structure illustrated in FIG. 13 can be formed.

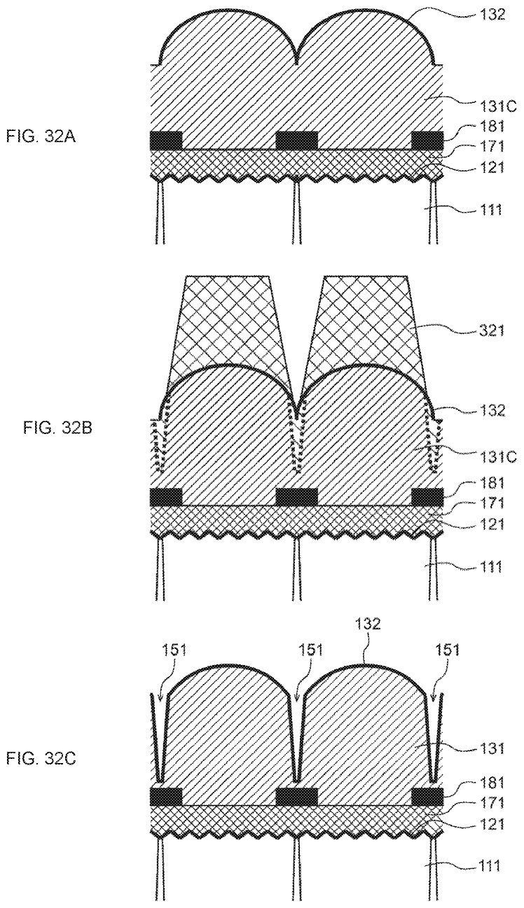

FIG. 32 illustrates an example of a manufacturing method including steps of forming the cross-sectional structure of FIG. 25. In this manufacturing method, steps after the antireflection layer 121, the intermediate layer 171, and the light-shielding film 181 are formed on the silicon substrate 111 are illustrated in order of steps.

In a step illustrated in A of FIG. 32, a layer 131C that contains silicon nitride (SiN) or the like, which is the material of the on-chip microlens 131, is formed in a lens shape, and the surface film 132 is further formed on a surface of the layer 131C. In a step illustrated in B of FIG. 32, an upper surface of the layer 131C is exposed in a pattern shape by lithography 321 to form a tapered pattern. In addition, the pattern of the lithography 321 and the like are scraped off by dry etching. The part to become the gap 151 is also removed.

In a step illustrated in C of FIG. 32, the surface film 132 is formed also on the surface of the gap 151. Through such steps, the cross-sectional structure illustrated in FIG. 25 can be formed.

### 2. Modifications

The above-described structures to which the present disclosure is applied are merely examples, and any structure of the first to eleventh examples of the structures may be combined with any of the other structures. For example, in the tenth example of the structure illustrated in FIGS. 25 and 26, an antireflection layer 122 may be formed instead of the antireflection layer 121.

The solid-state imaging device 10 can be a complementary metal oxide semiconductor (CMOS) type solid-state imaging device. This CMOS type solid-state imaging device can have a back-illuminated structure in which light is incident from an upper layer (back surface side) on the opposite side of a wiring layer side (front surface side) formed in a lower layer when viewed from a silicon substrate on which a photoelectric conversion region is formed. Note that the CMOS type solid-state imaging device may have a front-illuminated structure in which light is incident from the wiring layer side (front surface side).

Note that the structure to which the present disclosure is applied is not limited to the CMOS type solid-state imaging device, and can also be applied to a charge coupled device (CCD) type solid-state imaging device. Additionally, in the above description, the solid-state imaging device 10 has the configuration in which the first conductivity type is the p-type and the second conductivity type is the n-type, but the first conductivity type may be the n-type and the second conductivity type may be the p-type.

### (Configuration of Electronic Device)

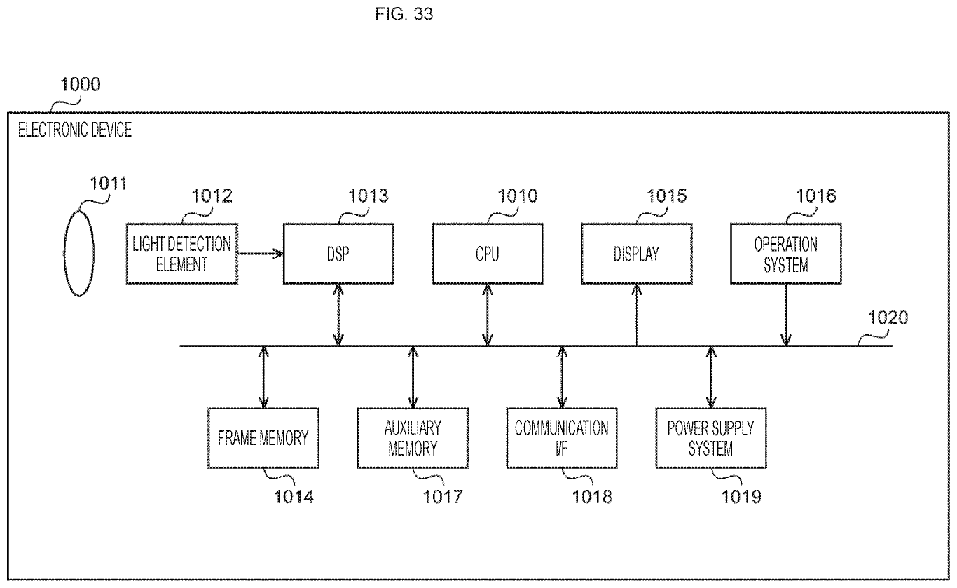

The photodetection device to which the present disclosure is applied can be mounted on an electronic device such as a smartphone, a tablet terminal, a mobile phone, a digital still camera, and a digital video camera. FIG. 33 is a block diagram illustrating a configuration example of an electronic device on which the photodetection device to which the present disclosure is applied is mounted.

In FIG. 33, an electronic device 1000 has an imaging system constituted by an optical system 1011 including a lens group, a light detection element 1012 having a function corresponding to the solid-state imaging device 10 in FIG. 1, and a digital signal processor (DSP) 1013 that is a camera signal processing unit. In the electronic device 1000, in addition to the imaging system, a central processing unit (CPU) 1010, a frame memory 1014, a display 1015, an operation system 1016, an auxiliary memory 1017, a communication I/F 1018, and a power supply system 1019 are connected to one another via a bus 1020.

The CPU 1010 controls operation of each unit of the electronic device 1000.

The optical system 1011 captures incident light (image light) from a subject, and forms an image on a light detection surface of the light detection element 1012. The light detection element 1012 converts an amount of incident light the image of which has been formed on the light detection surface by the optical system 1011 into an electric signal for each pixel, and outputs the electric signal as a pixel signal. The DSP 1013 performs predetermined signal processing on the signal output from the light detection element 1012.

The frame memory 1014 temporarily records image data of a still image or a moving image captured by the imaging system. The display 1015 is a liquid crystal display or an organic EL display, and displays a still image or a moving image captured by the imaging system. The operation system 1016 issues operation commands for a wide variety of functions of the electronic device 1000 in accordance with an operation by the user.

The auxiliary memory 1017 is a storage medium including a semiconductor memory such as a flash memory, and records image data of a still image or a moving image captured by the imaging system. The communication I/F 1018 has a communication module that supports a predetermined communication method, and transmits image data of a still image or a moving image captured by the imaging system to another apparatus via a network.

The power supply system 1019 appropriately supplies various types of power sources serving as power sources for operation to the CPU 1010, the DSP 1013, the frame memory 1014, the display 1015, the operation system 1016, the auxiliary memory 1017, and the communication I/F 1018 as supply targets.

Note that embodiments of the present disclosure are not limited to the embodiments described above, and various modifications may be made without departing from the scope of the present disclosure.

The effects described in the present specification are merely examples and are not limited, and other effects may be provided. Note that, in the present specification, assume that the expression of “in a plan view” is used to indicate a positional relationship of each part projected on a plane parallel to the surface of the silicon substrate (semiconductor substrate). In addition, assume that the expression of a “cross-sectional view” is used to indicate a positional relationship of each part projected on a plane perpendicular to the surface of the silicon substrate (semiconductor substrate).

Furthermore, the present disclosure can have the following configurations.

(1)

A photodetection device including:
a plurality of pixels each having a photoelectric conversion region;
an on-chip microlens formed corresponding to each pixel, in which
the on-chip microlens has a second refractive index that is a refractive index higher than a first refractive index, and
a gap having a tapered cross-sectional shape is formed as a region separating on-chip microlenses.
   (2)

The photodetection device according to (1), in which
the gap has a tapered shape that narrows toward a surface of a semiconductor substrate on which the photoelectric conversion region is formed.
   (3)

The photodetection device according to (1) or (2), in which
the first refractive index is 1.6, and
the second refractive index is a refractive index higher than 1.6.
   (4)

The photodetection device according to (2) or (3), in which
the gap penetrates to the surface of the semiconductor substrate in a cross-sectional view.
   (5)

The photodetection device according to (2) or (3), in which
the gap does not reach the surface of the semiconductor substrate in a cross-sectional view.
   (6)

The photodetection device according to any one of (1) to (5), in which
the gap is filled with air or an embedded film.
   (7)

The photodetection device according to any one of (1) to (6), in which
an entire periphery of the on-chip microlens is surrounded by the gap in a plan view.
   (8)

The photodetection device according to any one of (1) to (6), in which
the on-chip microlens has a part that does not become the gap in a diagonal direction in a plan view, and has the gap in four directions of upper, lower, left, and right directions.
   (9)

The photodetection device according to any one of (1) to (8), in which
a first layer that suppresses reflection of incident light is formed on a surface of a semiconductor substrate on which the photoelectric conversion region is formed.
   (10)

The photodetection device according to (9), in which
the first layer has a moth-eye structure or a recess having a predetermined shape in a plan view.
   (11)

The photodetection device according to (10), in which
the predetermined shape is a cross shape.
   (12)

The photodetection device according to any one of (1) to (11), in which
a second layer is formed between a semiconductor substrate on which the photoelectric conversion region is formed and the on-chip microlens.
   (13)

The photodetection device according to (12), in which
the gap does not penetrate the second layer in a cross-sectional view.
   (14)

The photodetection device according to any one of (1) to (13), in which
a light-shielding film that shields adjacent on-chip microlenses from incident light is formed.
   (15)

The photodetection device according to (14), in which
the gap does not penetrate the light-shielding film in a cross-sectional view.
   (16)

The photodetection device according to (2), in which,
when a width of a lower portion of the gap is 100 nm, a width of an upper portion of the gap is larger than 100 nm.
   (17)

The photodetection device according to (2), in which
the second refractive index is 1.9, and
the gap has a side wall having an angle at which incident light is totally reflected at an incident angle of 32°.
   (18)

The photodetection device according to any one of (1) to (17), in which
the on-chip microlens uses amorphous silicon (a-Si), silicon nitride (SiN), a high refractive index resin, tantalum (Ta), titanium (Ti), aluminum oxide (AlO), or a high refractive index metal oxide film as a material.
   (19)

The photodetection device according to any one of (1) to (18), in which
the photodetection device is configured as an image sensor that supports near-infrared rays.
   (20)

An electronic device on which a photodetection device is mounted, the photodetection device including:
a plurality of pixels each having a photoelectric conversion region; and
an on-chip microlens formed corresponding to each pixel, in which
the on-chip microlens has a second refractive index that is a refractive index higher than a first refractive index, and
a gap having a tapered cross-sectional shape is formed as a region separating on-chip microlenses.

### REFERENCE SIGNS LIST

10 Solid-state imaging device
100 Pixel
111 Silicon substrate
121, 122 Antireflection layer
131 On-chip microlens
132 Surface film
151 Gap
161 Embedded film
171, 172, 173 Intermediate layer
181 Light-shielding film
1000 Electronic device
1012 Light detection element

1. A photodetection device comprising:
a plurality of pixels each having a photoelectric conversion region;
an on-chip microlens formed corresponding to each pixel, wherein
the on-chip microlens has a second refractive index that is a refractive index higher than a first refractive index, and
a gap having a tapered cross-sectional shape is formed as a region separating on-chip microlenses.

2. The photodetection device according to claim 1, wherein
the gap has a tapered shape that narrows toward a surface of a semiconductor substrate on which the photoelectric conversion region is formed.

3. The photodetection device according to claim 1, wherein
the first refractive index is 1.6, and
the second refractive index is a refractive index higher than 1.6.

4. The photodetection device according to claim 2, wherein
the gap penetrates to the surface of the semiconductor substrate in a cross-sectional view.

5. The photodetection device according to claim 2, wherein
the gap does not reach the surface of the semiconductor substrate in a cross-sectional view.

6. The photodetection device according to claim 1, wherein
the gap is filled with air or an embedded film.

7. The photodetection device according to claim 1, wherein
an entire periphery of the on-chip microlens is surrounded by the gap in a plan view.

8. The photodetection device according to claim 1, wherein
the on-chip microlens has a part that does not become the gap in a diagonal direction in a plan view, and has the gap in four directions of upper, lower, left, and right directions.

9. The photodetection device according to claim 1, wherein
a first layer that suppresses reflection of incident light is formed on a surface of a semiconductor substrate on which the photoelectric conversion region is formed.

10. The photodetection device according to claim 9, wherein
the first layer has a moth-eye structure or a recess having a predetermined shape in a plan view.

11. The photodetection device according to claim 10, wherein
the predetermined shape is a cross shape.

12. The photodetection device according to claim 1, wherein
a second layer is formed between a semiconductor substrate on which the photoelectric conversion region is formed and the on-chip microlens.

13. The photodetection device according to claim 12, wherein
the gap does not penetrate the second layer in a cross-sectional view.

14. The photodetection device according to claim 1, wherein
a light-shielding film that shields adjacent on-chip microlenses from incident light is formed.

15. The photodetection device according to claim 14, wherein
the gap does not penetrate the light-shielding film in a cross-sectional view.

16. The photodetection device according to claim 2, wherein,
when a width of a lower portion of the gap is 100 nm, a width of an upper portion of the gap is larger than 100 nm.

17. The photodetection device according to claim 2, wherein
the second refractive index is 1.9, and
the gap has a side wall having an angle at which incident light is totally reflected at an incident angle of 32°.

18. The photodetection device according to claim 1, wherein
the on-chip microlens uses amorphous silicon (a-Si), silicon nitride (SiN), a high refractive index resin, tantalum (Ta), titanium (Ti), aluminum oxide (AlO), or a high refractive index metal oxide film as a material.

19. The photodetection device according to claim 1, wherein
the photodetection device is configured as an image sensor that supports near-infrared rays.

20. An electronic device on which a photodetection device is mounted, the photodetection device comprising:
a plurality of pixels each having a photoelectric conversion region; and
an on-chip microlens formed corresponding to each pixel, wherein
the on-chip microlens has a second refractive index that is a refractive index higher than a first refractive index, and
a gap having a tapered cross-sectional shape is formed as a region separating on-chip microlenses.
